(19) United States
(12) Patent Application Publication
(10) Pub. No.: US 2002/0121998 A1
(43) Pub. Date: Sep. 5, 2002

(54) Analog-to-digital converter that generates interrupt signal based on comparison results of comparator

(76) Inventor: Akihiro Yamazaki, Kawachi-gun (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/085,028

(22) Filed: Mar. 1, 2002

(30) Foreign Application Priority Data
Mar. 1, 2001 (JP) 2001-057319

(51) Int. Cl. H03M 1/12

(52) U.S. Cl. 341/155

(57) ABSTRACT

An A/D converter includes an analog/digital conversion section which converts a measured value obtained by measuring an object to be measured from analog data to digital data, a set value storage section which stores a set value, and a comparison section which compares the set value stored in the set value storage section and the measured value which is converted to the digital data by the analog/digital conversion section. A comparison result of the comparison section is a criterion for generating an interrupt signal which is inputted to a CPU in order to cause the CPU to perform processing based on the measured value.

### CROSS-REFERENCE TO RELATED APPLICATIONS

This application is based upon and claims the benefit of priority from the prior Japanese Patent Application No. 2001-057319, filed Mar. 1, 2001, the entire contents of which are incorporated herein by reference.

### BACKGROUND OF THE INVENTION

1. Field of the Invention

The present invention relates to an analog-to-digital converter that generates an interrupt signal based on comparison results of a comparator. More specifically, the invention relates to a technique to reduce the load of a CPU (central processing unit) in a microcomputer mounted with an analog-to-digital converter.

2. Description of the Related Art

Analog-to-digital converters (hereinafter referred to as A/D converters) have been conventionally used in a number of apparatuses in order to monitor various types of analog data. For example, they are used in a printer to confirm the remaining amount of toner and used in a PDA (personal digital assistants) to confirm the remaining amount of battery.

The configuration of the foregoing prior art A/D converter will now be described with reference to FIG. 1A. FIG. 1A is a block diagram of the prior art A/D converter.

As shown in FIG. 1A, the A/D converter 10 comprises an input channel (CH) selection circuit 11, an A/D conversion section 12, (m+1) storage registers 13-0 to 13-m, an input channel control circuit 14, a control circuit 15, and a storage register selection circuit 16.

Input channels CH0 to CHn are supplied with a plurality of measured values obtained by measuring objects to be measured. The measured values are analog data. The input channel control circuit 14 issues a command to the input channel selection circuit 11 to select one from among the input channels CH0 to CHn based on a command from the control circuit 15. The circuit 11 captures a measured value from the selected one of the input channels CH0 to CHn based on a command from the input channel control circuit 14. The input channel selection circuit 11 sends the captured measured value to the A/D conversion section 12. The section 12 operates in response to a command from the control circuit 15. Then, the section 12 converts the measured value captured by the input channel selection circuit 11 from analog data to digital data. The storage register selection circuit 16 selects one from among the storage registers 13-0 to 13-m based on a command from the control circuit 15. The selected storage register stores the measured value that is converted to the digital data by the A/D conversion section 12.

A flow of processing of the A/D converter having the above configuration will now be described with reference to FIG. 1B. FIG. 1B is a flowchart of processing of the A/D converter.

When A/D conversion starts, the control circuit 15 issues an A/D conversion startup command (step S10). In response to the A/D conversion startup command, the A/D conversion section 12 converts a measured value captured by the input channel selection circuit 11 from analog data to digital data. Then, the section 12 stores the digital data in one of the storage registers 13-0 to 13-m (step S11). The measured value is, for example, the remaining amount of toner of a printer. The A/D conversion startup command is issued periodically every fixed time or continuously by, e.g., a continuous conversion function of the A/D converter.

The control circuit 15 issues an interrupt signal to a CPU (not shown) each time the A/D conversion section 12 completes the A/D conversion (step S12). When the interrupt signal is issued, the CPU reads the measured values (digital data) out of the storage registers 13-0 to 13-m (step S13). The CPU compares the measured value with a preset value on software (step S14). The preset value is, for example, the amount of toner as an index to give an alarm when the remaining amount of toner becomes small.

If the remaining amount of toner is smaller than the preset value as a result of the comparison (step S15), the CPU performs given processing (step S16). This processing is to display the comparison result on a display device or raise an alarm. As a result of the processing, a user of the printer is notified that the remaining amount of toner becomes small. On the other hand, if the remaining amount of toner is larger than the preset value, the CPU does not perform further processing but ends the processing.

As described above, the prior art A/D converter issues an interrupt signal in the CPU each time A/D conversion is completed. The CPU performs interrupt processing each time the interrupt signal is issued. In the interrupt processing, the CPU reads a result of A/D conversion out of the A/D converter. Then, the result of A/D conversion is compared with the preset value by software processing to determine which is larger.

However, the above-described system tends to increase the load of the CPU. This tendency will be described with reference to FIG. 2. FIG. 2 is a timing chart showing a relationship between time and each of normal processing and interrupt processing of the CPU.

Assuming that A/D conversion is performed periodically at times t1, t2, t3 and t4 as shown in FIG. 2, an interrupt signal does not fail to issue at each of the times. Therefore, the CPU stops the normal processing each time the interrupt signal issues and has to compare the measured value that is converted to the digital data with the preset value.

A/D conversion should be repeated in a short time especially when supervisory functions need to be tightened. Explaining it with reference to FIG. 2, a time interval Δt between times t1, t2, t3 and t4 has to be shortened. Interrupt processing should be performed each time A/D conversion is done. For this reason, the proportion of the interrupt processing (readout, A/D conversion, and determination of results of conversion) to the entire processing of the CPU increases. In other words, the burden of the CPU due to the interrupt processing is very increased.

As described above, there were cases where the prior art A/D converter increased in the burden of software processing for supervisory functions in the CPU and its response to the other processing became slow.

### BRIEF SUMMARY OF THE INVENTION

An A/D converter according to an aspect of the present invention comprises an analog/digital conversion section which converts a measured value obtained by measuring an object to be measured from analog data to digital data, a set value storage section which stores a set value, and a comparison section which compares the set value stored in the set value storage section and the measured value which is converted to the digital data by the analog/digital conversion section, a comparison result of the comparison section being a criterion for generating an interrupt signal which is inputted to a CPU in order to cause the CPU to perform processing based on the measured value.

A signal processing method of an A/D converter according to an aspect of the present invention comprises converting a measured value obtained by measuring an object to be measured from analog data to digital data, comparing the measured value converted to the digital data with a set value, and outputting an interrupt signal to a CPU when a result of comparison between the measured value and the set value satisfies a given result.

A microcomputer according to an aspect of the present invention comprises an A/D converter including an analog/digital conversion section which converts a measured value obtained by measuring an object to be measured from analog data to digital data, a set value storage section which stores a set value, and a comparison section which compares the set value stored in the set value storage section and the measured value which is converted to the digital data by the analog/digital conversion section, and a control section which generates the interrupt signal based on the comparison result of the comparison section, and a CPU which performs processing based on the measured value which is converted to the digital data by the A/D converter, in response to the interrupt signal generated from the control section.

### BRIEF DESCRIPTION OF THE SEVERAL VIEWS OF THE DRAWING

FIG. 1A is a block diagram of a prior art A/D converter;

FIG. 1B is a flowchart showing a flow of processing of a prior art microcomputer;

FIG. 2 is a conceptual diagram showing a flow of processing of a CPU mounted on the prior art microcomputer;

FIG. 3A is a block diagram of a microcomputer according to a first embodiment of the present invention;

FIG. 3B is a flowchart showing a flow of processing of the microcomputer according to the first embodiment of the present invention;

FIG. 4A is a graph showing a relationship between the remaining amount of toner of a printer and time;

FIG. 4B is a conceptual diagram showing a flow of processing of a CPU that is performed in accordance with variations in the remaining amount of toner shown in FIG. 4A;

FIG. 5A is a block diagram of a microcomputer according to a second embodiment of the present invention;

FIG. 5B is a flowchart showing a flow of processing of the microcomputer according to the second embodiment of the present invention;

FIG. 6 is a block diagram of a microcomputer according to a third embodiment of the present invention;

FIGS. 7A and 7B are block diagrams of a microcomputer according to a fourth embodiment of the present invention;

FIG. 7C is a flowchart showing a flow of processing of the microcomputer according to the fourth embodiment of the present invention;

FIG. 8A is a block diagram of a microcomputer according to a fifth embodiment of the present invention;

FIG. 8B is a conceptual diagram of a memory space in which processing programs of the CPU are stored; and

FIG. 9 is a block diagram of a microcomputer according to a sixth embodiment of the present invention.

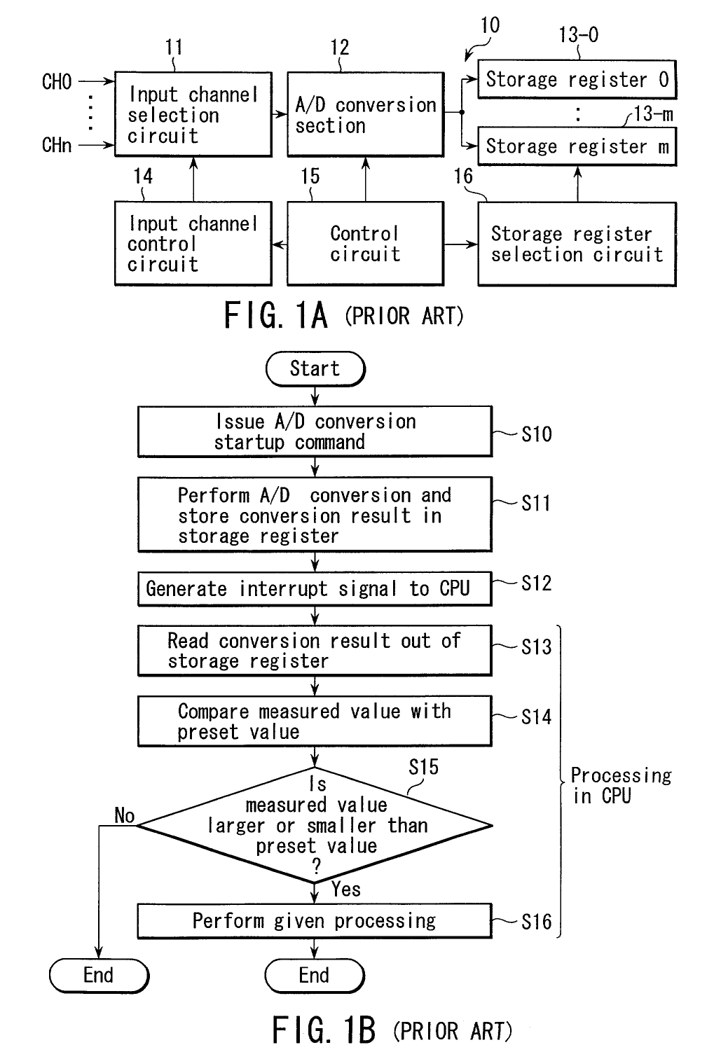

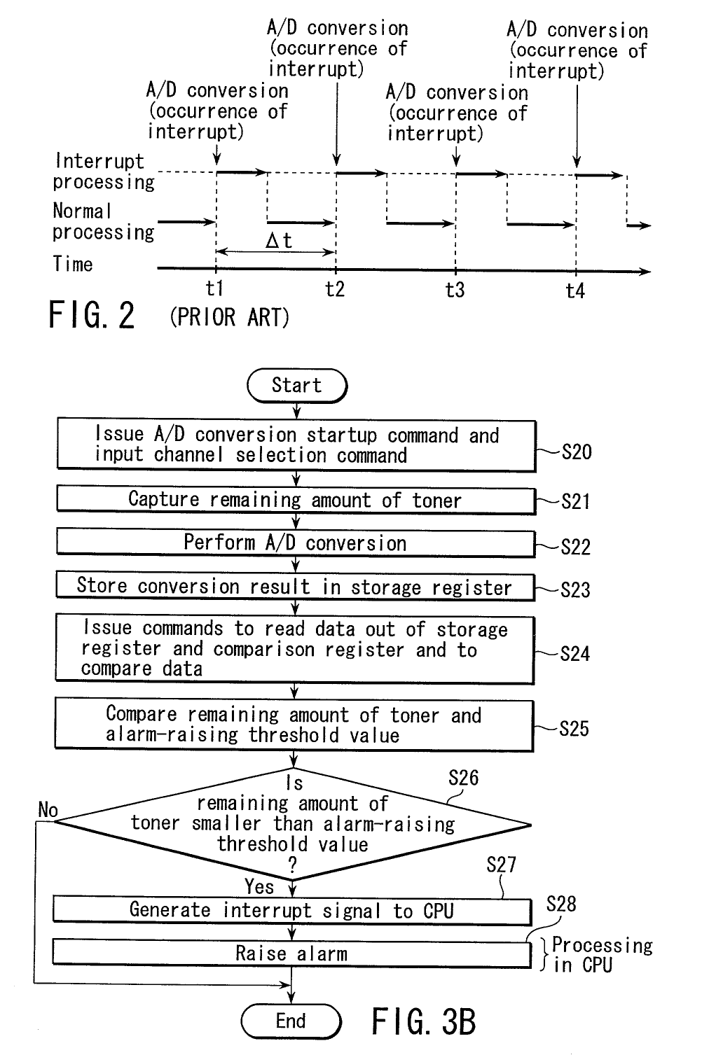

### DETAILED DESCRIPTION OF THE INVENTION

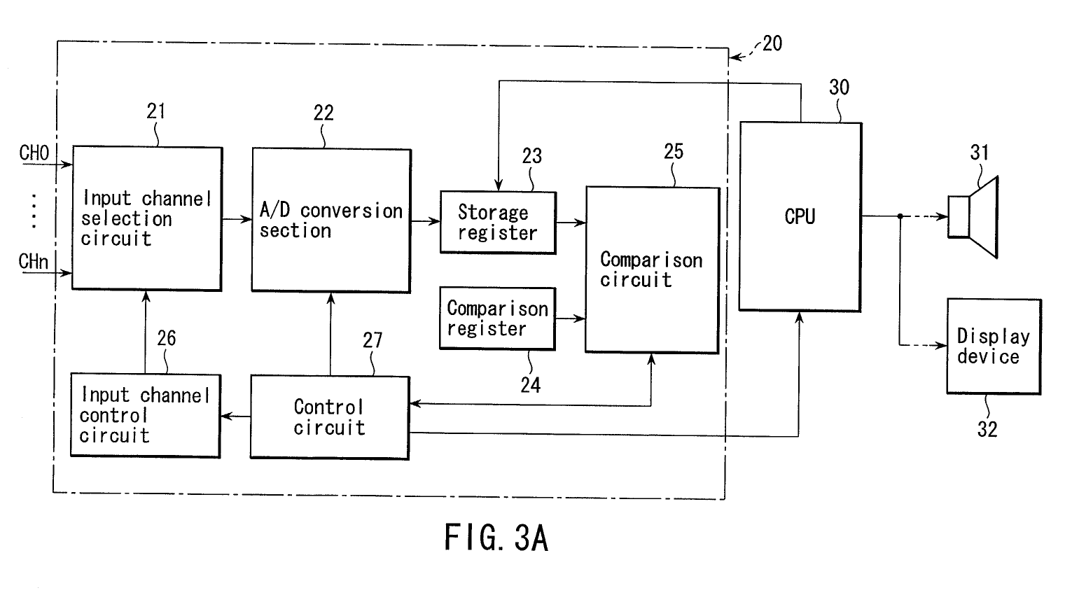

An A/D converter according to a first embodiment of the present invention will now be described with reference to FIG. 3A. FIG. 3A is a block diagram showing a main part of a one-chip microcomputer mounted with the A/D converter.

As shown in FIG. 3A, an A/D converter 20 comprises an input channel (CH) selection circuit 21, an A/D conversion section 22, a storage register 23, a comparison register 24, a comparison circuit 25, an input channel control circuit 26, and a control circuit 27.

Input channels CH0 to CHn are supplied with measured values obtained by measuring objects to be measured. The input channels CH0 to CHn are assigned to their respective objects to be measured. The measured values are analog data. The input channel control circuit 26 issues an input channel selection command to the input channel selection circuit 21 to select one from among the input channels based on a command from the control circuit 27. The input channel selection command is to select one from among the input channels CH0 to CHn and capture a measured value from the selected input channel. The input channel selection circuit 21 captures the measured value from the selected input channel in response to the selection command from the input channel control circuit 26. The input channel selection circuit 21 supplies the A/D conversion section 22 with the measured value captured from the selected input channel.

The A/D conversion section 22 operates in response to a command from the control circuit 27 and converts the measured value, which is captured by the input channel selection circuit 21, from analog data to digital data.

The storage register 23 stores a measured value that is converted to the digital data by the A/D conversion section 22.

The comparison register 24 stores a given set value that is preset for each type of an object to be measured. The set value is digital data.

The comparison circuit 25 operates in response to a command from the control circuit 27. The circuit 25 compares the measured value stored in the storage register 23 and the set value stored in the comparison register 24.

The control circuit 27 issues a command to the input channel control circuit 26, A/D conversion section 22, and comparison circuit 25. In accordance with comparison results of the comparison circuit 25, the control circuit 27 supplies an interrupt signal to a CPU 30 provided on the same chip as that of the A/D converter 20.

The CPU 30 performs given interrupt processing in response to the interrupt signal supplied from the control circuit 27. A result of the interrupt processing in the CPU 30 is transmitted to an external device such as a speaker 31 and a display device 32.

An operation of the one-chip microcomputer so configured will now be described with reference to FIG. 3B. FIG. 3B is a flowchart showing a flow of processing of the one-chip microcomputer shown in FIG. 3A. The first embodiment is directed to the case where the microcomputer mounted on a printer monitors the remaining amount of toner.

In the A/D converter 20, the control circuit 27 issues an A/D conversion startup command to the A/D conversion section 22. The control circuit 27 also issues an input channel selection command to the input channel control circuit 21 (step S20).

In response to the input channel selection command, the input channel control circuit 21 instructs the input channel selection circuit 21 to capture data (measured value) that is supplied to a predetermined input channel. In response to the instruction, the input channel selection circuit 21 captures a measured value from the predetermined input channel (step S21). The measured value is analog data indicating the remaining amount of toner.

The A/D conversion section 22 A/D-converts the measured value captured by the input channel selection circuit based on the A/D conversion startup command (step S22). A result (digital data) of the A/D conversion is stored in the storage register 23 (step S23). The A/D conversion startup command output from the control circuit 21 can be executed periodically every fixed time or continuously by, e.g., a continuous conversion function of the A/D converter.

When the A/D conversion of the A/D conversion section 22 is completed, the control circuit 27 outputs a data readout instruction and a data comparison instruction to the comparison circuit 25 (step S24). The comparison circuit 25 takes a measured value and a set value out of the storage register 23 and comparison register 24, respectively in response to the readout instruction. The measured value taken out of the storage register 23 corresponds to the remaining amount of toner that is converted from analog data to digital data by the A/D conversion described above. The set value taken out of the comparison register 24 corresponds to the amount of toner as an index to give an alarm indicating that the remaining amount of toner is small. In other words, the set value is digital data indicating a threshold value for raising an alarm.

In response to the comparison instruction, the comparison circuit 25 compares the remaining amount of toner taken out of the storage register 23 and the alarm-raising threshold value taken out of the comparison register 24 (step S25).

If the remaining amount of toner is smaller than the alarm-raising threshold value as a result of the comparison of the comparison circuit 25 (step S26), the control circuit 27 supplies an interrupt signal to the CPU 30 (step S27). The CPU 30 supplied with the interrupt signal stops a normal operation and performs interrupt processing (step S28). The interrupt processing is to cause the speaker 31 to raise an alarm, display the above comparison result on the display device 32, and the like. Consequently, a user is notified that the remaining amount of toner becomes small. On the other hand, if the remaining amount of toner is larger than the alarm-raising threshold value (step S26), the control circuit 27 does not produce any interrupt signal to the CPU 30. Thus, the CPU 30 continues performing the normal operation.

As described above, the control circuit 27 can output the interrupt signal to the CPU 30 or the comparison circuit 25 itself can output the interrupt signal to the CPU 30 in accordance with the comparison result. Furthermore, a new circuit for generating an interrupt signal can be provided.

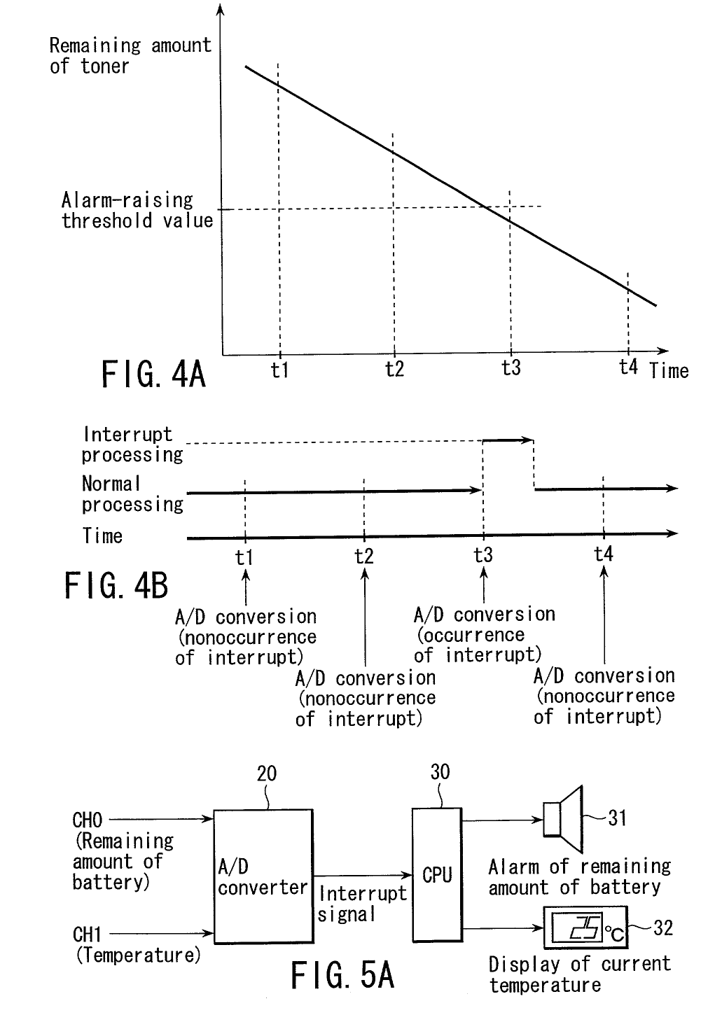

In the microcomputer according to the first embodiment described above, the A/D converter compares a measured value with a given set value (threshold value). In accordance with a result of the comparison, an interrupt signal in the CPU is generated. It is thus possible to cause an interrupt only when processing is required in the CPU or when the measured value becomes equal to or exceeds the threshold value. Consequently, the CPU 30 need not perform any useless interrupt processing unlike in the prior art. The burden of processing of the CPU can greatly be decreased. The advantages of the first embodiment will be described more specifically with reference to FIGS. 4A and 4B. FIG. 4A shows a relationship between the remaining amount of toner of a printer and time. FIG. 4B shows a relationship between time and each of normal processing and interrupt processing of the CPU.

Assume that the remaining amount of toner of the printer decreases with the passage of time as shown in FIG. 4A and consequently assume that the remaining amount of toner becomes smaller than the alarm-raising threshold value between times t2 and t3. If under these conditions the A/D converter periodically performs A/D-conversion at times t1, t2, t3 and t4 as shown in FIG. 4B, the measured value does not become smaller than the set value before time t3; therefore, the interrupt processing of the CPU, which is based on the conversion result of the A/D converter, is required only at time t3. In the prior art microcomputer, however, an interrupt signal is generated at all the times including times t1, t2 and t4 when the CPU ought not to require any interrupt processing. The CPU had to stop the normal operation and perform interrupt processing whenever an interrupt signal was generated.

In the microcomputer according to the first embodiment of the present invention, the CPU can continue the normal processing since no interrupt signals to the CPU are produced at time t1, t2 or t4 other than time t3. The interrupt processing has only to be performed only at time t3 when the remaining amount of toner is actually reduced. The burden of processing of the CPU can thus be decreased.

When a supervisory function is tightened, the advantages of the first embodiment become greater. In order to tighten the supervisory function, a time interval for A/D conversion need to be lessened. Assume that the time interval is shortened by half in FIG. 4B. In the prior art, the CPU has to perform seven interrupt processings between times t1 and t4. Of these seven interrupt processings, it is only one processing that is actually significant. According to the first embodiment, the comparison circuit 25 certainly performs seven comparison processings. However, it is only at time t3 when the remaining amount of toner decreases that the CPU performs the interrupt processing. It is therefore possible to tighten the supervisory function without increasing the burden of the CPU.

The A/D converter of the first embodiment can be achieved simply by adding both a comparison register and a comparison circuit to the circuit arrangement of the prior art A/D converter with almost no increase in the area of the circuit.

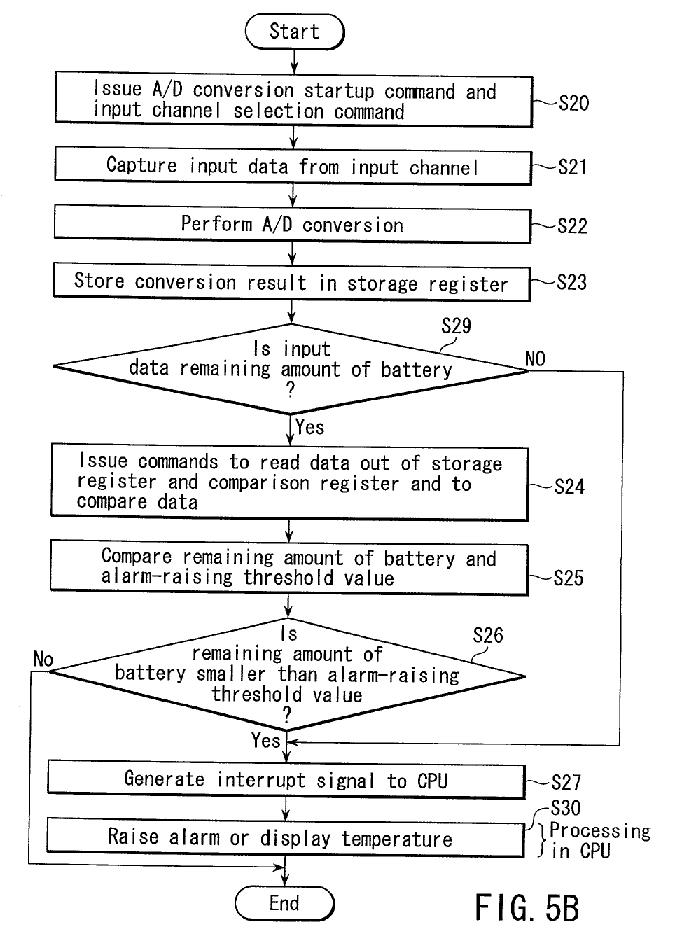

An A/D converter according to a second embodiment of the present invention will now be described with reference to FIGS. 5A and 5B. FIG. 5A is a block diagram of a microcomputer including the A/D converter.

The configuration of the microcomputer according to the second embodiment is identical with that of the microcomputer according to the first embodiment. Assume that the microcomputer of the second embodiment monitors the remaining amount of battery and temperature. The remaining amount of battery is input to an input channel CH0 and temperature data is input to an input channel CH1. As in the first embodiment, when the remaining amount of battery becomes smaller than a certain threshold value, a speaker 31 raises an alarm. A display section 32 displays the current temperature at all times. A comparison register 24 stores an alarm-raising threshold value of the remaining amount of battery.

An operation of the microcomputer having the above configuration will now be described with reference to FIGS. 3A, 5A and 5B. FIG. 5B is a flowchart showing a flow of processing of the above microcomputer.

In the A/D converter 20, a control circuit 27 issues an A/D conversion startup command to an A/D conversion section 22. The control circuit 27 also issues an input channel selection command to an input channel control circuit 26 (step S20).

In response to the input channel selection command, the input channel control circuit 26 instructs an input channel selection circuit 21 to capture a measured value from a given input channel. The circuit 21 thus captures the measured value from the given input channel in accordance with the instruction (step S21). When the circuit 21 selects the input channel CH0, it captures data of the remaining amount of battery. When the circuit 21 selects the input channel CH1, it captures temperature data. It is needless to say that these measured values are analog data.

The A/D conversion section 22 performs A/D conversion of the measured value captured by the input channel selection circuit 21 based on the A/D conversion startup command (step S22). A result of the A/D conversion (digital data) is stored in a storage register 23 (step S23).

The control circuit 27 determines whether the captured measured value is the remaining amount of battery (step S29). In other words, the control circuit 27 determines whether the measured value requires the processing of the CPU each time A/D conversion is performed. If the captured measured value is the remaining amount of battery, the CPU need not perform any processing based on the measured value each time the measured value is converted to digital data. The processing of the CPU is required only when the remaining amount of battery becomes smaller than the alarm-raising threshold value. On the other hand, if the captured measured value is temperature data, the CPU has to perform the processing each time A/D conversion is made. Then, the current temperature has to be displayed on the display section.

If, therefore, the captured measured value is the remaining amount of battery, the flow goes to the next step S24. The step S24 and its subsequent steps is the same as that in the first embodiment. When the remaining amount of battery is smaller than the alarm-raising threshold value, an interrupt signal to the CPU 30 is generated. If the interrupt signal is generated, the CPU 30 stops a normal operation and performs interrupt processing (step S30) and instructs the speaker 31 to raise an alarm.

When the captured measured value is determined as temperature data in step S29, the steps S24 to S26 is omitted. In other words, the control circuit 27 generates an interrupt signal to the CPU 30 unconditionally without performing any comparison processing in a comparison circuit 25. Thus, the CPU 30 stops the normal operation and performs interrupt processing (step S30) and instructs the display section 32 to display the current temperature thereon.

The remaining amount of battery is input to the input channel CH0 of the A/D converter and temperature data is input to the input channel CH1 thereof. In the A/D converter, generally, an input channel CH is assigned in advance to each input signal by software. Therefore, the control circuit 27 need not perform any new processing regarding the determination processing of step S29. Usually the control circuit 27 already recognizes a result of the above determination processing when the circuit 27 issues an input channel selection command to the input channel control circuit 26 in step S20.

As described above, the A/D converter processes the following two types of data:

(1) A measured value in itself is significant:

This type of data is directed to, for example, a temperature monitor. When a measured value is temperature data, it needs to be transmitted to the outside and, in this case, the processing of the CPU is required each time A/D conversion is made.

(2) Not a measured value in itself but a relationship between a measured value and a specific threshold value is significant:

This type of data is directed to, for example, checking of the remaining amount of toner of a printer and a power supply monitor. In other words, the value of the remaining amount of toner or battery is not significant in itself. A relationship between the value and the threshold value is necessary information. The first embodiment focuses attention on the processing of only this type of data.

According to the A/D converter of the second embodiment, it is determined whether a measured value is data to be processed step by step in the CPU before the comparison circuit compares the measured value with a set value. In other words, it is determined whether the measured value is data belonging to the type (1) or data belonging to the type (2). When the measured value is data to be processed step by step (data belonging to the step (1)), an interrupt signal to the CPU is generated unconditionally. Therefore, the A/D converter of the second embodiment can process the data measured by an object not only belonging to the step (2) but also the data measured by an object belonging to the step (1).

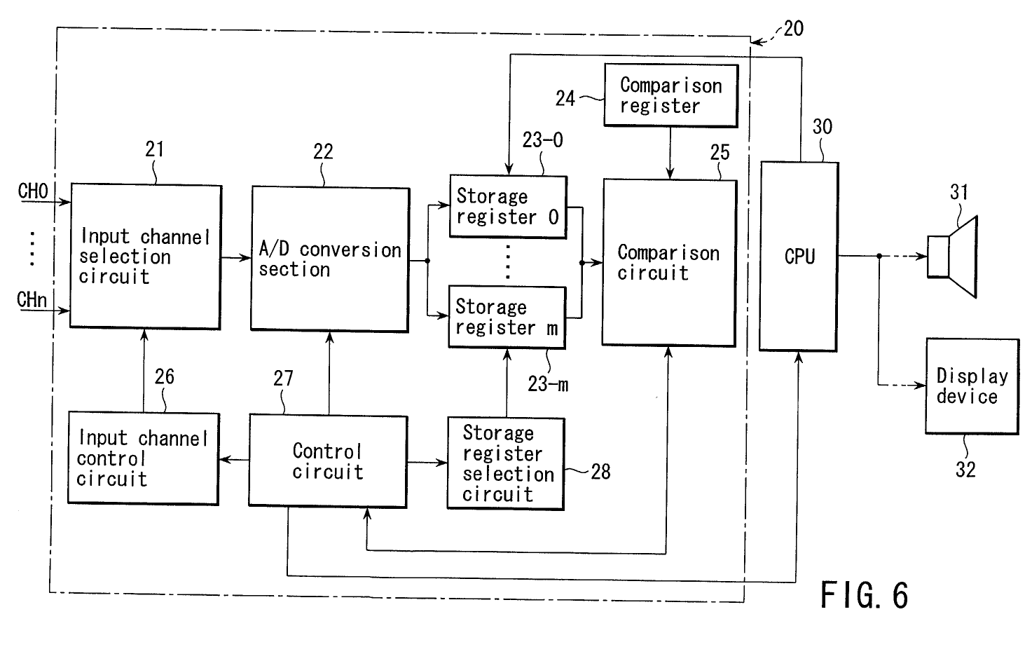

An A/D converter according to a third embodiment of the present invention will now be described with reference to FIG. 6. FIG. 6 is a block diagram showing part of a one-chip microcomputer mounted with the A/D converter.

As illustrated in FIG. 6, the A/D converter of the third embodiment comprises a plurality of (m+1) storage registers 23-0 to 23-m in addition to the components of the A/D converters according to the first and second embodiments. The A/D converter of the third embodiment also comprises a storage register selection circuit 28 that selects one of the storage registers 23-0 to 23-m in response to a command from the control circuit 27.

An operation of the one-chip microcomputer having the above configuration will now be described with reference to FIG. 3B or FIG. 5B.

In step S20, the control circuit 27 issues a storage register selection command as well as an AD conversion startup command and an input channel selection command to the storage register selection circuit 28. The storage register selection command is to determine which storage register should be used to store a measured value captured by the input channel selection circuit 21. Based on the storage register selection command, the storage register selection circuit 28 selects a storage register for storing the measured value.

After that, the step S21 and its subsequent steps in FIGS. 3B and 5B is performed. When a measured value is data (the remaining amount of toner, etc.) to be processed step by step in the CPU, the comparison circuit 25 compares a measured value stored in the storage register and a set value stored in the comparison register. Then, the control circuit 27 generates an interrupt signal to the CPU 30 based on the comparison result.

Since the A/D converter according to the third embodiment includes a plurality of storage registers, it can hold a plurality of measured values. When the A/D converter is supplied with measurement results obtained from a plurality of objects to be measured, it can hold the measurement results by assigning the storage registers to the objects to be measured.

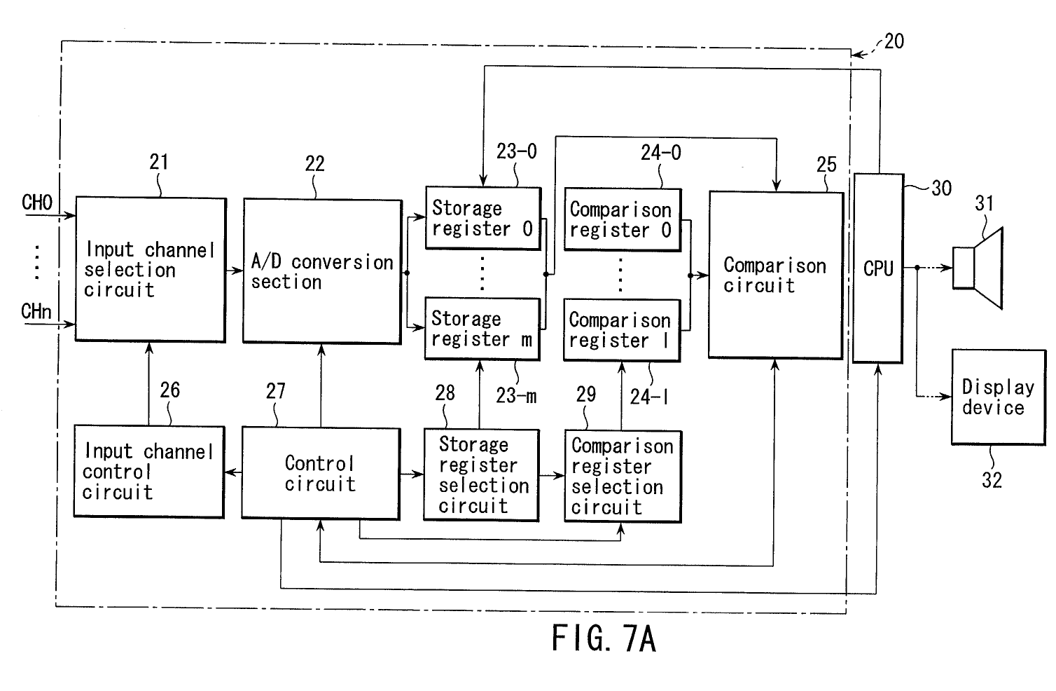

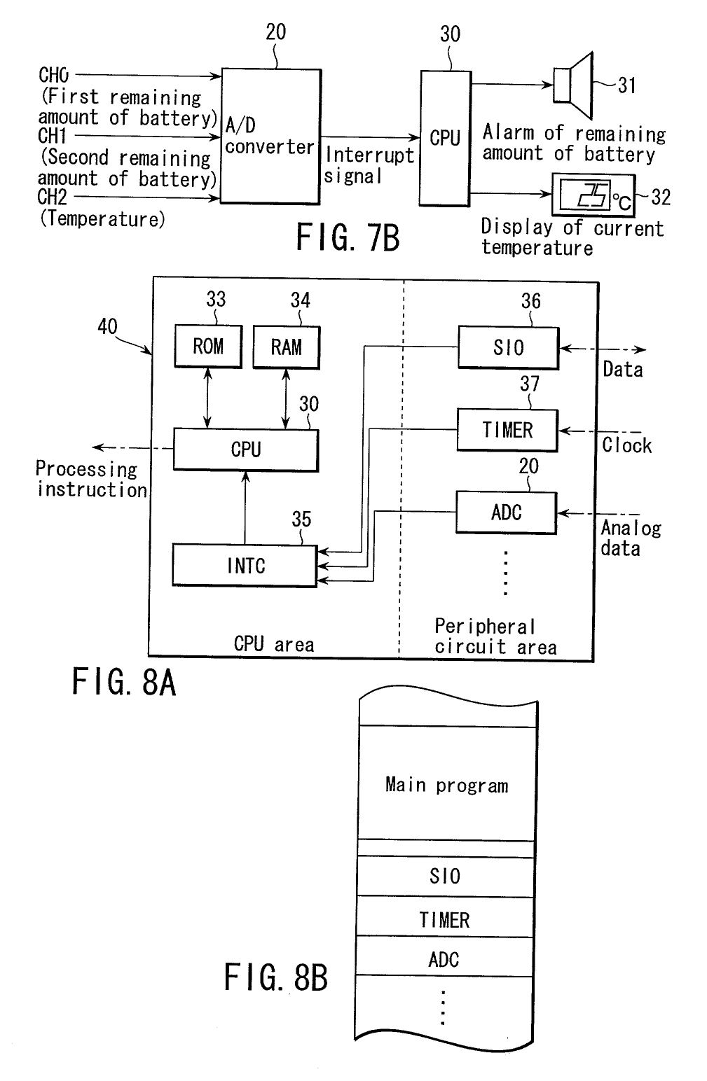

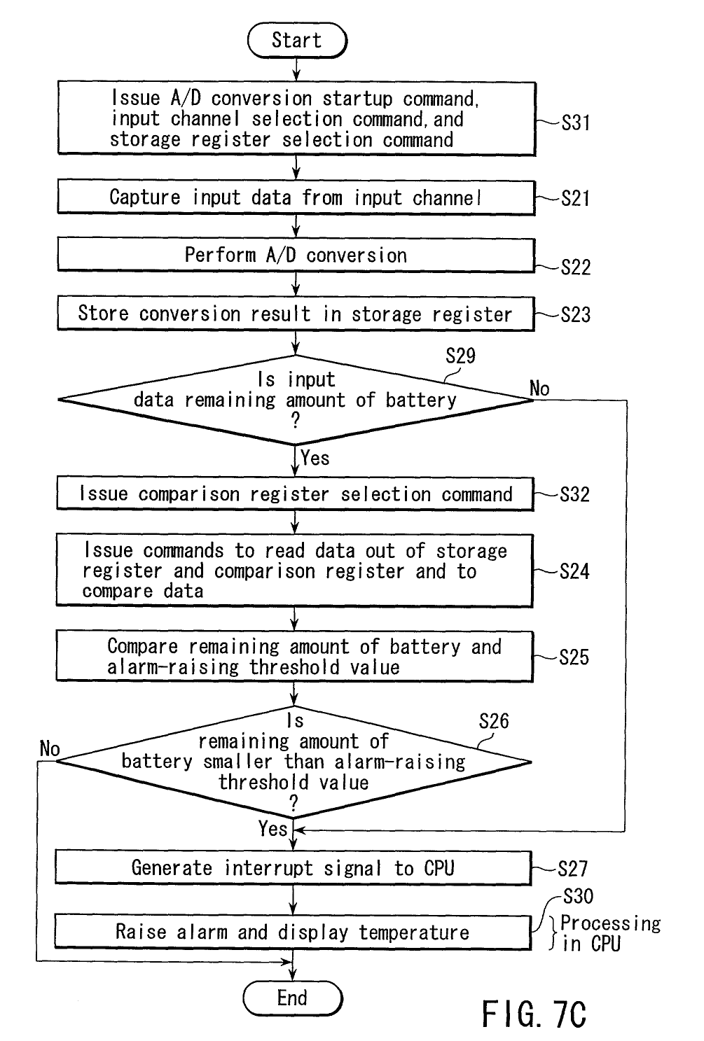

An A/D converter according to a fourth embodiment of the present invention will now be described with reference to FIG. 7A. FIG. 7A is a block diagram showing part of a one-chip microcomputer mounted with the A/D converter.

As illustrated in FIG. 7A, the A/D converter of the fourth embodiment comprises a plurality of (l+1) comparison registers 24-0 to 24-1 in addition to the components of the A/D converter of the third embodiment. The A/D converter of the fourth embodiment also comprises a comparison register selection circuit 29 that selects one of the comparison registers 24-0 to 24-1 in response to a command from the control circuit 27.

The control circuit 27 instructs the storage register selection circuit 28 to determine which storage register should be used to store a measured value captured by tie input channel selection circuit 21. In response to the instruction, the circuit 28 selects a storage register for storing a measured value that is converted to the digital data by A/D conversion.

The control circuit 27 instructs the comparison register selection circuit 29 to select one of the comparison registers 24-0 to 24-1. The circuit 29 selects one of the comparison registers 24-0 to 24-2 in accordance with the type of a measured value (object to be measured). Then, the comparison circuit 25 compares a measured value with a set value stored in the comparison register selected by the comparison register selection circuit 29.

An operation of the one-chip microcomputer having the above configuration will now be described with reference to FIGS. 7A to 7C. FIG. 7B is a block diagram of the one-chip microcomputer and FIG. 7C is a flowchart showing a flow of processing of the one-chip microcomputer.

Assume that the different remaining amounts of battery (first and second remaining amounts of battery) are input to the input channels CH0 and CH1, respectively and temperature data is input to the input channel CH2, as shown in FIG. 7B. As in the second embodiment, assume that a speaker 31 raises an alarm, when each of the first and second remaining amounts of battery becomes smaller than a threshold value fixed therefor. A display section 32 displays the current temperature at all times. Assume that the comparison registers 24-0 and 24-1 store set values (alarm-raising threshold values) corresponding to the first and second remaining amounts of battery, respectively.

In the A/D converter 20, the control circuit 27 issues an A/D conversion startup command to the A/D conversion section 22. The control circuit 27 also issues an input channel selection command to the input channel control circuit 21. Further, the control circuit 27 issues a storage register selection command to the storage register selection circuit 29 (step S31). When the input channel control circuit 21 selects the input channel CH0, the storage register selection circuit 29 selects the storage register 23-1. When the circuit 21 selects the input channel CH1, the circuit 29 selects the storage register 23-2. When the circuit 21 selects the input channel CH2, the circuit 29 selects the storage register 23-3.

In response to the input channel selection command, the input channel control circuit 21 instructs the input channel selection circuit 21 to capture a measured value from a given input channel. In response to the instruction, the circuit 21 captures the measured value from the given input channel (step S21). When the input channel CH0 is selected, the first remaining amount of battery is captured. When the input channel CH1 is selected, the second remaining amount of battery is captured. When the input channel CH2 is selected, temperature data is captured. Needless to say, these measured values are analog data.

The A/D conversion section 22 performs A/D conversion of a measured value captured by the input channel selection circuit 21 in response to the A/D conversion startup command (step S22). The result of the A/D conversion (digital data) is stored in the storage register 23 that is selected by the storage register selection circuit 29 (step S23).

The control circuit 27 determines whether the captured measured value corresponds to the remaining amount of battery (step S29). When the A/D converter 20 selects the input channel CH2 and captures the temperature data, the measured value need not be compared with a set value. Thus, the flow goes to step S27 and the control circuit 27 generates an interrupt signal to the CPU 30. Then, the CPU 30 stops a normal operation to perform interrupt processing (step S30) and display the current temperature on the display section 32.

On the other hand, if the A/D converter 20 selects the input channels CH0 and CH1 and the captured data correspond to the first and second remaining amounts of battery, they need to be compared with a set value. In this case, the control circuit 27 issues a comparison register selection command to the comparison register selection circuit 29 (step S32). The circuit 29 selects one of comparison registers 24-0 and 24-1 in response to the comparison register selection command. When the input channel CH0 is selected to capture the first remaining amount of battery, the comparison register selection circuit 29 selects the comparison register 24-0. When the second remaining amount of battery is captured, the circuit 29 selects the comparison register 24-1.

The control circuit 27 instructs the comparison circuit 25 to read a measured value and a set value out of the storage register and comparison register and compare them with each other (step S24). The processing after that is the same as that in the first embodiment. If the remaining amount of battery is smaller than the alarm-raising threshold value, the control circuit 27 generates an interrupt signal to the CPU 30. When the interrupt signal is generated, the CPU 30 stops a normal operation to perform interrupt processing (step S30) and instructs the speaker 31 to raise an alarm.

According to the A/D converter of the fourth embodiment, a plurality of set values are held by a plurality of comparison registers. If, therefore, there are a plurality of objects to be measured, the set values can selectively be used for each of the objects to be measured. For example, the plurality of remaining amounts of battery can be confirmed by different threshold values using a single A/D converter. Moreover, a plurality of comparison registers can be assigned to one object to be measured and different set values can be stored in the respective registers. In this case, the objects can be compared with a plurality of threshold values. For example, the remaining amount of battery can be confirmed in a plurality of steps or compared in sequence with a plurality of set values.

An A/D converter according to a fifth embodiment of the present invention will now be described with reference to FIGS. 8A and 8B. FIG. 8A is a block diagram of a one-chip microcomputer mounted with the A/D converter.

As illustrated in FIG. 8A, a one-chip microcomputer 40 can roughly be divided into two areas of a CPU area and a peripheral circuit area. The CPU area includes a CPU 30, a ROM 33, a RAM 34, and an interrupt control circuit INTC 35. The peripheral circuit area includes a serial-input-output-controller (SIO) 36, a timer circuit (TIMER) 37, and an A/D converter (ADC) 20. The SIO 36 performs transmission/ reception of data between the one-chip microcomputer 40 and the outside by radio or wire communication. The SIO 36 gives an interrupt instruction to the CPU area after the transmission/reception of data. The TIMER 37 counts clocks to measure predetermined elapsed time. After a predetermined lapse of time, the TIMER 37 gives an interrupt instruction to the CPU area. The ADC 20 corresponds to the A/D converters according to the first to fourth embodiments described above and gives an interrupt instruction to the CPU area after given processing is performed.

The INTC 35 supplies an interrupt control signal to the CPU 30 in response to the interrupt instructions from the SIO 36, TIMER 37 and ADC 20. The INTC 35 assigns priority to the interrupt instructions from the SIO 36, TIMER 37 and ADC 20. When the interrupt instructions issued from the respective circuits conflict with each other, the INTC 35 outputs an interrupt control signal corresponding to each of the circuits according to the priority. The CPU 30 operates in accordance with the programs stored in the ROM 33. FIG. 8B is a conceptual diagram showing a model of a memory space of the ROM 33. As shown in FIG. 8B, the ROM 33 stores interrupt processing programs that are executed when an interrupt occurs due to the SIO, TIMER and ADC, in addition to the main programs. The CPU 30 carries out a normal operation in accordance with the main programs stored in the ROM 33. When the INTC 35 generates an interrupt control signal, the CPU 30 stops the normal operation and then reads out the interrupt processing programs in response to the interrupt control signal. Then, the interrupt processing is performed based on the readout interrupt processing programs. In some cases, the CPU 30 gives a processing instruction to the outside. If the interrupt processing is completed, the CPU 30 read out the main programs again and returns to the normal operation.

As described above, the CPU 30 is usually supplied with interrupt instructions from a plurality of circuits. The CPU 30 has to stop the normal operation to perform interrupt processing each time it is supplied with an interrupt instruction. It is thus necessary to inhibit useless interrupt processing from being performed as soon as possible. According to the microcomputer of the fifth embodiment, at least the ADC 20 gives an interrupt instruction only when the processing of the CPU 30 is essential. The load of the CPU 30 can thus be lessened and the operation efficiency of the microcomputer 40 can be improved. Consequently, the response of the CPU 30 to the processing performed by the SIO, TIMER, and the like is improved.

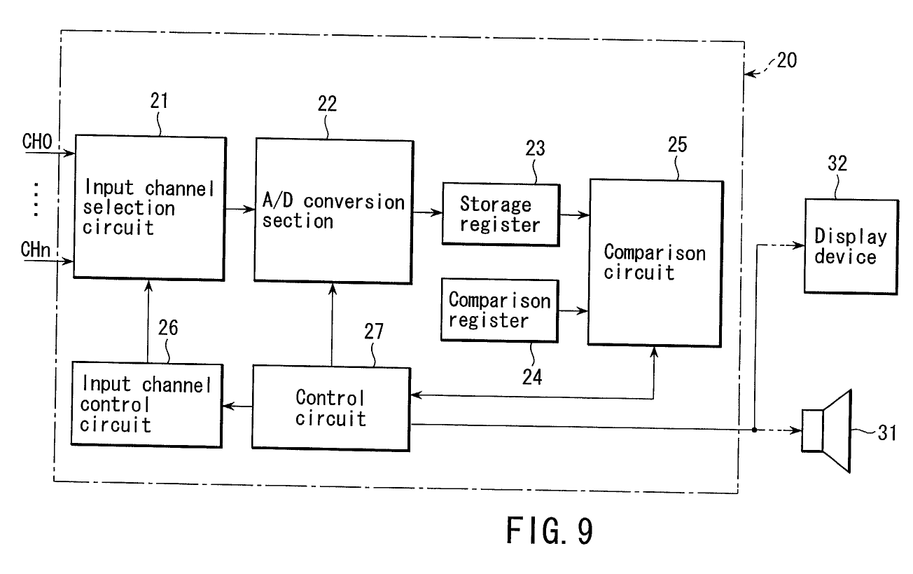

An A/D converter according to a sixth embodiment of the present invention will now be described with reference to FIG. 9. FIG. 9 is a block diagram showing part of a one-chip microcomputer mounted with the A/D converter.

As shown in FIG. 9, the configuration of the A/D converter according to the sixth embodiment is similar to that of the A/D converter according to the first embodiment. In the sixth embodiment, however, the A/D converter 20 itself performs specific processing. In other words, a control circuit 27 does not give an interrupt instruction to the CPU. Instead, the control circuit 27 gives processing instructions to a display device 32, a speaker 31 and the like in accordance with the comparison results of a comparison circuit 25. In this case, the processing programs for the display device 32 and speaker 31 can be incorporated into the control circuit 27 or read out of the ROM or the like provided outside the control circuit 27.

The sixth embodiment allows processing without giving an interrupt instruction to the CPU. Thus, the load of the CPU mounted on the microcomputer can greatly be decreased. The sixth embodiment can be applied to the A/D converters according to not only the first embodiment but also the second to fourth embodiments.

According to the first to sixth embodiments described above, the interrupt processing to the CPU is performed only when it is actually required in the CPU. According to the sixth embodiment, the A/D converter itself performs specific processing without performing any interrupt processing to the CPU. The burden of the CPU can be reduced accordingly.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An A/D converter comprising:
an analog/digital conversion section which converts a measured value obtained by measuring an object to be measured from analog data to digital data;
a set value storage section which stores a set value; and
a comparison section which compares the set value stored in the set value storage section and the measured value which is converted to the digital data by the analog/digital conversion section, a comparison result of the comparison section being a criterion for generating an interrupt signal which is inputted to a CPU in order to cause the CPU to perform processing based on the measured value.

2. The A/D converter according to claim 1, further comprising a control section which generates the interrupt signal based on the comparison result of the comparison section.

3. The A/D converter according to claim 2, wherein when the object to be measured requires the processing of the CPU performed based on the measured value each time the measured value is converted to digital data, the control section generates an interrupt signal to the CPU unconditionally after the analog/digital conversion section converts the measured value from analog data to digital data and, when the object to be measured requires the processing of the CPU performed based on the measured value only when the measured value satisfies a specific relation with the set value, the control section instructs the comparison section to compare the measured value with the set value and generates an interrupt signal to the CPU in accordance with the comparison result after the analog/digital conversion section converts the measured value from analog data to digital data.

4. The A/D converter according to claim 1, further comprising a conversion result storage section which stores the measured value that is converted to digital data by the analog/digital conversion section, and wherein the comparison section reads the measured value out of the conversion result storage section.

5. The A/D converter according to claim 4, wherein the conversion result storage section includes conversion result storage registers and a storage register selection circuit which selects one of the conversion result storage registers, and the measured value converted to digital data by the analog/digital conversion section is stored in the one of the conversion result storage registers selected by the storage register selection circuit.

6. The A/D converter according to claim 1, wherein the set value storage section includes comparison registers which store a plurality of set values, respectively and a comparison register selection circuit which selects one of the comparison registers in accordance with the object to be measured, and the comparison section compares the measured value converted to the digital data by the analog/digital conversion section with a set value stored in the one of the comparison registers selected by the comparison register selection circuit.

7. The A/D converter according to claim 1, wherein an interrupt signal to the CPU is generated when the measured value exceeds the set value as a result of comparison of the comparison section.

8. The A/D converter according to claim 1, wherein an interrupt signal to the CPU is generated when the measured value is equal to the set value as a result of comparison of the comparison section.

9. The A/D converter according to claim 1, wherein the set value is a threshold value to generate the interrupt signal.

10. An A/D converter comprising:
an analog/digital conversion section which converts a measured value obtained by measuring an object to be measured from analog data to digital data;
a set value storage section which stores a set value; and
a comparison section which compares the set value stored in the set value storage section and the measured value which is converted to the digital data by the analog/digital conversion section; and
a control section which performs processing based on the measured value based on a criterion of a comparison result of the comparison section.

11. A signal processing method of an A/D converter, comprising:
converting a measured value obtained by measuring an object to be measured from analog data to digital data;
comparing the measured value converted to the digital data with a set value; and
outputting an interrupt signal to a CPU when a result of comparison between the measured value and the set value satisfies a given result.

12. The signal processing method according to claim 11, further comprising stopping a normal operation of the CPU and performing processing based on the measured value when the interrupt signal is output.

13. The signal processing method according to claim 11, further comprising determining whether the object to be measured requires the processing of the CPU performed based on the measured value each time the measured value is converted to digital data or requires the processing of the CPU based on the measured value only when the measured value satisfies a specific relation with the set value, before the measured value and the set value are compared with each other,
wherein when it is determined that the object to be measured requires the processing of the CPU performed based on the measured value each time the measured value is converted to digital data, an interrupt signal is output to the CPU unconditionally without comparing the measured value and the set value with each other and, when the object to be measured requires the processing of the CPU based on the measured value only when the measured value satisfies a specific relation with the set value, the measured value and the set value are compared with each other.

14. The signal processing method according to claim 11, further comprising:
storing the set value having a given value in a comparison register in advance; and
storing the measured value converted to the digital data in a conversion result storage register,
wherein the comparing the measured value with the set value includes reading the set value out of the comparison register and reading the measured value out of the conversion result storage register.

15. A microcomputer comprising:
an A/D converter including an analog/digital conversion section which converts a measured value obtained by measuring an object to be measured from analog data to digital data, a set value storage section which stores a set value, and a comparison section which compares the set value stored in the set value storage section and the measured value which is converted to the digital data by the analog/digital conversion section, and a control section which generates the interrupt signal based on the comparison result of the comparison section; and
a CPU which performs processing based on the measured value which is converted to the digital data by the A/D converter, in response to the interrupt signal generated from the control section.
